(19) United States
(12) Patent Application Publication
(10) Pub. No.: US 2023/0370042 A1
(43) Pub. Date: Nov. 16, 2023

(54) BULK ACOUSTIC WAVE DEVICE

(71) Applicant: Murata Manufacturing Co., Ltd., Nagaokakyo-shi (JP)

(72) Inventors: Tetsuya KIMURA, Nagaokakyo-shi (JP); Kentaro NAKAMURA, Nagaokakyo-shi (JP)

(21) Appl. No.: 18/226,289

(22) Filed: Jul. 26, 2023

Related U.S. Application Data
(63) Continuation of application No. PCT/JP2022/012314, filed on Mar. 17, 2022.

(30) Foreign Application Priority Data
Mar. 24, 2021 (JP) 2021-049423

(51) Int. Cl. H03H 9/02; H03H 9/17; H03H 9/13

(52) U.S. Cl. CPC H03H 9/02157; H03H 9/173; H03H 9/133

(57) ABSTRACT

A bulk acoustic wave device includes a scandium-containing aluminum nitride film on a first electrode on a substrate, and a second electrode on the scandium-containing aluminum nitride film, the first electrode and the second electrode overlapping each other with the scandium-containing aluminum nitride film interposed therebetween. In the scandium-containing aluminum nitride film, along a thickness direction, in a first area on a first electrode side, a third area on a second electrode side, and a second area as a center area in the thickness direction between the first area and the third area, an orientation ratio in the first area is lower than an orientation ratio in the second area, or an orientation ratio in the third area is higher than the orientation ratio in the second area.

### CROSS REFERENCE TO RELATED APPLICATIONS

This application claims the benefit of priority to Japanese Patent Application No. 2021-049423 filed Mar. 24, 2021 and is a Continuation Application of PCT Application No. PCT/JP2022/012314 filed on Mar. 17, 2022. The entire contents of each application are hereby incorporated herein by reference.

### BACKGROUND OF THE INVENTION

### 1. Field of the Invention

The present invention relates to a bulk acoustic wave device including a scandium-containing aluminum nitride film.

### 2. Description of the Related Art

Conventionally, a bulk acoustic wave device using a scandium (Sc)-containing aluminum nitride (AlN) film, that is, a ScAlN film, as a piezoelectric film, has been known. For example, in Japanese Unexamined Patent Application Publication No. 2009-010926, a BAW device using a scandium-added aluminum nitride film is disclosed. Also in US2015/0084719 A1, a bulk acoustic wave device having a similar structure is disclosed.

### SUMMARY OF THE INVENTION

In the bulk acoustic wave devices described in Japanese Unexamined Patent Application Publication No. 2009-010926 and US2015/0084719 A1, when the Sc concentration increases, piezoelectricity is enhanced.

However, in the bulk acoustic wave devices described in Japanese Unexamined Patent Application Publication No. 2009-010926 and US2015/0084719 A1, the characteristics of the bulk acoustic wave devices may be degraded.

Preferred embodiments of the present invention provide bulk acoustic wave devices each including a ScAlN film with less occurrence of degradation in characteristics.

A bulk acoustic wave device according to a preferred embodiment of the present invention includes a first electrode, a scandium-containing aluminum nitride film provided on the first electrode, a second electrode provided on the scandium-containing aluminum nitride film and overlapping the first electrode with the scandium-containing aluminum nitride film interposed therebetween, and a substrate supporting the scandium-containing aluminum nitride film. In the scandium-containing aluminum nitride film, when, along a thickness direction, an area positioned on a first electrode side is taken as a first area, an area positioned on a second electrode side is taken as a third area, and a center area in the thickness direction between the first area and the third area is taken as a second area, an orientation ratio in the first area is lower than an orientation ratio in the second area.

Further, in a preferred embodiment of the present invention, there is also provided a bulk acoustic wave device including a first electrode, a scandium-containing aluminum nitride film provided on the first electrode, a second electrode provided on the scandium-containing aluminum nitride film and overlapping the first electrode with the scandium-containing aluminum nitride film interposed therebetween, and a substrate supporting the scandium-containing aluminum nitride film. In the scandium-containing aluminum nitride film, when, along a thickness direction, an area positioned on a first electrode side is taken as a first area, an area positioned on a second electrode side is taken as a third area, and a center area in the thickness direction between the first area and the third area is taken as a second area, an orientation ratio in the third area is higher than an orientation ratio in the second area.

According to preferred embodiments of the present invention, it is possible to provide bulk acoustic wave devices each including a scandium-containing aluminum nitride film with less occurrence of degradation in characteristics.

The above and other elements, features, steps, characteristics and advantages of the present invention will become more apparent from the following detailed description of the preferred embodiments with reference to the attached drawings.

### BRIEF DESCRIPTION OF THE DRAWINGS

FIGS. 1A and 1B are a front sectional view and a plan view, respectively, of a bulk acoustic wave device according to a preferred embodiment of the present invention.

FIG. 2 is a schematic sectional view for describing a first area to a third area in a ScAlN film of the bulk acoustic wave device of the present preferred embodiment of the present invention.

### DETAILED DESCRIPTION OF THE PREFERRED EMBODIMENTS

With reference to the drawings, specific preferred embodiments of the present invention are described below to clarify the present invention.

Note that each preferred embodiment described in the specification is merely an example and partial replacement or combination of structures can be made between different preferred embodiments.

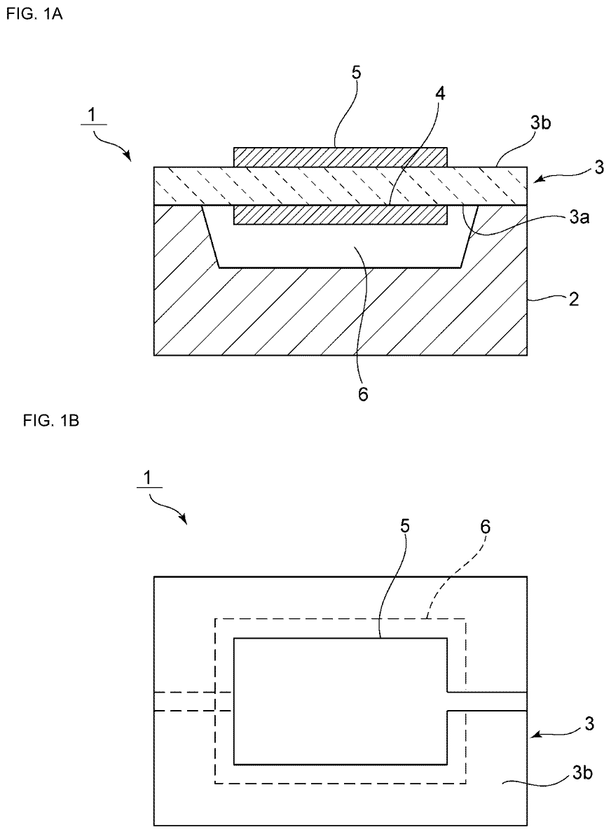

FIG. 1A is a front sectional view of a bulk acoustic wave device according to a preferred embodiment of the present invention, and FIG. 1B is a plan view thereof.

A bulk acoustic wave device 1 includes a substrate 2. On an upper surface of the substrate 2, a concave portion is provided. A scandium-containing aluminum nitride (ScAlN) film 3 is laminated so as to cover the concave portion of the upper surface of the substrate 2. The ScAlN film 3 includes a first principal surface 3a and a second principal surface 3b opposite to the first principal surface 3a. The first principal surface 3a is laminated on the upper surface of the substrate 2. With this, a cavity portion 6 is provided.

On the first principal surface 3a, a first electrode 4 is provided. On the second principal surface 3b, a second electrode 5 is provided. The first electrode 4 is taken as a lower electrode and the second electrode 5 is taken as an upper electrode. The first electrode 4 and the second electrode 5 overlap each other with the ScAlN film 3 interposed therebetween. This overlapping area is an excitation area. With an alternating-current electric field applied between the first electrode 4 and the second electrode 5, a bulk acoustic wave (BAW) as an acoustic wave is excited. The bulk acoustic wave device 1 is a bulk acoustic wave device in which an acoustic wave propagating through the ScAlN film 3 is mainly a BAW.

The cavity portion 6 is provided so as not to inhibit excitation of the BAW in the ScAlN film 3. Therefore, the cavity portion 6 is positioned below the first and second electrodes 4 and 5.

The substrate 2 is made of an appropriate insulating material or semiconductor. As this material, silicon, glass, GaAs, ceramics, quartz, or the like can be cited. In the present preferred embodiment, the substrate 2 is a high-resistance silicon substrate.

Note that the first electrode 4 and the second electrode 5 are made of an appropriate metal or alloy. As this material, a metal such as Ti, Mo, Ru, W, Al, Pt, Ir, Cu, Cr, or Sc or an alloy using any of these metals can be cited. Also, each of the first and second electrodes 4 and 5 may be a multilayer body of a plurality of metal films.

The ScAlN film 3 can be formed with an appropriate method such as sputtering or CVD. In the present preferred embodiment, the ScAlN film 3 is formed by using an RF magnetron sputter apparatus, for example.

On the occasion of sputtering described above, sputtering is performed by using a first target made of Al and a second target made of Sc in an atmosphere of nitrogen gas. That is, a ScAlN film is formed with binary sputtering. In this case, the orientation ratio of the ScAlN film can be controlled by adjusting the sputtering conditions. As sputtering conditions, the magnitude of RF power, gas pressure, gas flow path, and the composition or purity of the material of a target can be cited.

Note that the orientation ratio of the formed ScAlN film can be checked by using ASTAR (registered trademark). This ASTAR uses automated crystal orientation mapping-TEM method (ACOM-TEM method).

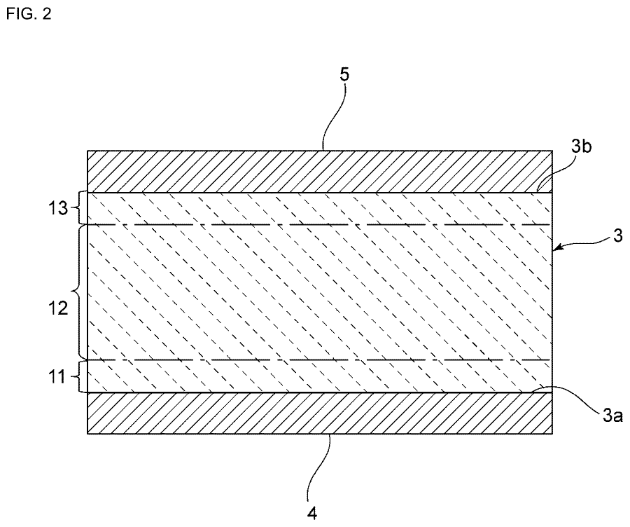

Features of the bulk acoustic wave device 1 are described with reference to FIG. 2.

FIG. 2 is a schematic sectional view for describing a first area to a third area in a ScAlN film of the bulk acoustic wave device of the present preferred embodiment.

As depicted in FIG. 2, the ScAlN film 3 includes a first area 11 to a third area 13 in a thickness direction. The second area 12 is an area positioned at the center in the thickness direction of the ScAlN film 3. The first area 11 is an area positioned on a first electrode 4 side. The third area 13 is an area positioned on a second electrode 5 side.

In the bulk acoustic wave device 1, the orientation ratio of the first area 11 is set lower than the orientation ratio of the second area 12. Also, the orientation ratio in the third area 13 is set higher than the orientation ratio of the second area 12. With this, degradation in characteristics can be reduced or prevented.

When the orientation ratio in the first area 11 is lower than the orientation ratio in the second area 12, the film stress of the ScAlN film 3 can be made small. Thus, the ScAlN film 3 peeling from the first electrode 4, and warpage also are reduced or prevented. Thus, degradation in characteristics is reduced or prevented.

On the other hand, when the orientation ratio in the third area 13 is higher than the orientation ratio in the second area 12, the orientation of the second electrode 5 formed on the third area 13 is enhanced. Thus, the second electrode 5 with less crystal defects can be formed. Therefore, piezoelectricity can be enhanced.

More preferably, the orientation ratio of the first area 11 is lower than the orientation ratio of the second area 12, and the orientation ratio of the third area 13 is higher than the orientation ratio of the second area 12. In that case, degradation in characteristics can be more effectively reduced or prevented.

Note that the above-described orientation ratios are values obtained by measurement with automated crystal orientation mapping-TEM method. In this case, the tolerance is about ±2.5, for example.

Here, “orientation ratio” in the present application is defined as follows. Firstly, an inverse pole figure is obtained with the above-described ACOM-TEM method. From the obtained inverse pole figure, an area with a deviation of the crystal with respect to a reference crystal axis was confirmed. Here, “(area in which a deviation of the crystal axis is within a range of five degrees)/(entire target area)” is taken as “orientation ratio”. Also, as for “deviation of the crystal axis”, for example, when Si(100) is used as a support substrate, it is thought that ScAlN has a c-axis orientation with the normal direction being <0001> with respect to the Si(100) plane. A deviation from this c-axis orientation is defined as a “deviation of the crystal axis”.

Here, while the thickness of the second area 12 as a center area varies depending on the film thickness of the ScAlN film 3, the thickness is preferably within a range larger than or equal to about 58% and smaller than or equal to about 86% of the film thickness, for example. In that case, favorable resonant characteristics can be obtained. The thickness of the first area 11 is preferably about 7% or larger and about 21% or smaller of the film thickness of the entire ScAlN film 3 and is preferably about 50 nm or larger and about 80 nm or smaller as absolute values, for example. In that case, warpage and peeling of the ScAlN film 3 less tend to occur, and therefore degradation in characteristics further less tends to occur.

The thickness of the third area 13 is preferably about 7% or larger and about 21% or smaller of the film thickness of the entire ScAlN film 3 and is preferably about 50 nm or larger and about 80 nm or smaller as absolute values, for example. When the thickness of the third area 13 is about 7% or larger of the film thickness of the ScAlN film 3, for example, crystallinity of the second electrode 5 can be more effectively enhanced. When the thickness of the third area 13 is about 21% or smaller of the film thickness of the ScAlN film 3, for example, degradation in piezoelectricity of the ScAlN film 3 further less tends to occur.

Next, description is made based on a more specific example of experiment. As described above, by the RF magnetron sputter apparatus, the ScAlN film 3 having a thickness of about 540 nm, for example, was formed on the first electrode 4. By controlling the conditions of sputtering in this case, a sample 1 having a scandium concentration of about 6.8 atom % of the entire film and a sample 2 having a scandium concentration of about 11.7 atom % of the entire film were prepared, for example.

Note that in the sample 1, the orientation ratio of the first area 11 was about 99.5%, the orientation ratio of the second area 12 was about 99.7%, and the orientation ratio of the third area 13 was about 99.9%, for example.

On the other hand, in the sample 2, the orientation ratio of the first area 11 was about 98.2%, the orientation ratio of the second area 12 was about 99.5%, and the orientation ratio of the third area 13 was about 100%, for example.

By using the ScAlN films 3 of the above-described sample 1 and sample 2, the bulk acoustic wave devices 1 were fabricated. Note that the material of the first and second electrodes 4 and 5 was Mo.

As a result, in both of the bulk acoustic wave devices 1 using the ScAlN films 3 of the sample 1 and the sample 2, warpage and peeling of the ScAlN film 3 was able to be reduced or prevented. Also, crystallinity of the second electrode 5 was also able to be effectively enhanced. Therefore, in both cases, it was discovered and confirmed that degradation in characteristics is reduced or prevented.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A bulk acoustic wave device comprising:
a first electrode;
a scandium-containing aluminum nitride film provided on the first electrode;
a second electrode provided on the scandium-containing aluminum nitride film and overlapping the first electrode with the scandium-containing aluminum nitride film interposed therebetween; and
a substrate supporting the scandium-containing aluminum nitride film; wherein
in the scandium-containing aluminum nitride film, when, along a thickness direction, an area positioned on a first electrode side is taken as a first area, an area positioned on a second electrode side is taken as a third area, and a center area in the thickness direction between the first area and the third area is taken as a second area, an orientation ratio in the first area is lower than an orientation ratio in the second area.

2. The bulk acoustic wave device according to claim 1, wherein the first electrode is a lower electrode.

3. The bulk acoustic wave device according to claim 1, wherein a concave portion is provided on an upper surface of the substrate.

4. The bulk acoustic wave device according to claim 3, wherein the scandium-containing aluminum nitride film covers the concave portion to define a cavity portion.

5. The bulk acoustic wave device according to claim 4, wherein the cavity portion is below the first and second electrodes so as not to inhibit excitation of a bulk acoustic wave in the scandium-containing aluminum nitride film.

6. The bulk acoustic wave device according to claim 1, wherein the substrate is made of an insulating material or a semiconductor material.

7. The bulk acoustic wave device according to claim 1, wherein the first electrode and the second electrode are made of a metal or a metal alloy, and each include one or more metal films.

8. The bulk acoustic wave device according to claim 1, wherein a thickness of the second area is about 58% to about 86% of a film thickness of the scandium-containing aluminum nitride film.

9. The bulk acoustic wave device according to claim 1, wherein a thickness of the first area is about 7% to about 21% of a film thickness of the scandium-containing aluminum nitride film.

10. The bulk acoustic wave device according to claim 1, wherein a thickness of the third area is about 7% to about 21% of a film thickness of the scandium-containing aluminum nitride film.

11. A bulk acoustic wave device comprising:
a first electrode;
a scandium-containing aluminum nitride film provided on the first electrode;
a second electrode provided on the scandium-containing aluminum nitride film and overlapping the first electrode with the scandium-containing aluminum nitride film interposed therebetween; and
a substrate supporting the scandium-containing aluminum nitride film; wherein
in the scandium-containing aluminum nitride film, when, along a thickness direction, an area positioned on a first electrode side is taken as a first area, an area positioned on a second electrode side is taken as a third area, and a center area in the thickness direction between the first area and the third area is taken as a second area, an orientation ratio in the third area is higher than an orientation ratio in the second area.

12. The bulk acoustic wave device according to claim 11, wherein an orientation ratio of the first area is lower than the orientation ratio of the second area.

13. The bulk acoustic wave device according to claim 11, wherein a concave portion is provided on an upper surface of the substrate.

14. The bulk acoustic wave device according to claim 13, wherein the scandium-containing aluminum nitride film covers the concave portion to define a cavity portion.

15. The bulk acoustic wave device according to claim 14, wherein the cavity portion is below the first and second electrodes so as not to inhibit excitation of a bulk acoustic wave in the scandium-containing aluminum nitride film.

16. The bulk acoustic wave device according to claim 11, wherein the substrate is made of an insulating material or a semiconductor material.

17. The bulk acoustic wave device according to claim 11, wherein the first electrode and the second electrode are made of a metal or a metal alloy, and each include one or more metal films.

18. The bulk acoustic wave device according to claim 11, wherein a thickness of the second area is about 58% to about 86% of a film thickness of the scandium-containing aluminum nitride film.

19. The bulk acoustic wave device according to claim 11, wherein a thickness of the first area is about 7% to about 21% of a film thickness of the scandium-containing aluminum nitride film.

20. The bulk acoustic wave device according to claim 11, wherein a thickness of the third area is about 7% to about 21% of a film thickness of the scandium-containing aluminum nitride film.
